(19) United States
(12) Patent Application Publication
(10) Pub. No.: US 2026/0344129 A1
(43) Pub. Date: Oct. 29, 2026

(54) LED PACKAGE STRUCTURE WITH HIGH ADHESION AND METHOD FOR MANUFACTURING THE SAME

(71) Applicant: LITE-ON TECHNOLOGY CORPORATION, TAIPEI CITY (TW)

(72) Inventors: CHI-MING WU, TAIPEI CITY (TW); CHIH-LI YU, New Taipei City (TW)

(21) Appl. No.: 19/653,130

(22) Filed: Apr. 21, 2026

Related U.S. Application Data
(60) Provisional application No. 63/793,064, filed on Apr. 23, 2025.

(30) Foreign Application Priority Data
Sep. 17, 2025 (CN) 202511327348.6

(51) Int. Cl. H10H 20/853; H10H 20/01

(52) U.S. Cl. CPC H10H 20/853; H10H 20/0362

(57) ABSTRACT

An LED package structure with high adhesion and a method for manufacturing the same. The LED package structure includes a conductive carrier, a package housing, at least one LED unit, a light-permeable component, and a barrier component. The conductive carrier includes a functional region and a non-functional region that surrounds the functional region and has at least one metal sectional surface. The package housing encapsulates the conductive carrier and has an accommodating cavity, and the metal sectional surface is exposed through the package housing. The at least one LED unit is disposed in the accommodating cavity and electrically connected to the functional region. The light-permeable component is disposed in the accommodating cavity and encapsulates the at least one LED unit. The barrier component is connected to the non-functional region, so as to isolate the metal sectional surface exposed through the package housing from the external environment.

### CROSS-REFERENCE TO RELATED PATENT APPLICATION

This application claims the benefit of priority to the U.S. Provisional Patent Application Ser. No. 63/793,064 filed on Apr. 23, 2025, which application is incorporated herein by reference in its entirety.

This application claims the benefit of priority to China Patent Application No. 202511327348.6, filed on Sep. 17, 2025 in People’s Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an LED package structure, and more particularly to an LED package structure with high adhesion and a method for manufacturing the same.

### BACKGROUND OF THE DISCLOSURE

A packaging structure, which is integrally formed from a resin material such as an epoxy molding compound (EMC) and a lead frame, is currently one of the common packaging types, and is widely used in the packaging of various electronic components. However, the interfacial adhesion between the epoxy molding compound and the lead frame is relatively poor, which often leads to delamination between the resulting package body and the lead frame, thus affecting the reliability of the overall packaging structure.

Furthermore, said packaging structure is a single component obtained by a singulation process. In the singulation process, a plurality of connecting regions between a plurality of lead frame units and a plurality of package bodies formed on the connecting regions are severed simultaneously, resulting in a portion of the metal being exposed on side surfaces of the package body. The exposed metal portions are susceptible to contact with oxygen, moisture, or corrosive gases in the external environment, which may cause damage or performance degradation of LED components. This problem is particularly pronounced under high humidity or harsh environmental conditions.

Therefore, there is still a need for further improvement in LED packaging structure designs, so as to resolve the problems caused by the exposed metal portions.

### SUMMARY OF THE DISCLOSURE

In response to the above-referenced technical inadequacies, the present disclosure provides an LED package structure with high adhesion and a method for manufacturing the same. One main concept of the present disclosure is to encapsulate a conductive carrier with a package housing and dispose a barrier component on a non-functional region of the conductive carrier, so as to isolate at least one metal sectional surface of the conductive carrier that is a cut surface exposed through the package housing from the external environment. Therefore, potential weaknesses at the packaging interface can be improved. Such a design enhances the environmental adaptability of the LED packaging structure, making it suitable for applications requiring high reliability.

In order to solve the above-mentioned problems, one of the technical aspects adopted by the present disclosure is to provide an LED package structure with high adhesion, which includes a conductive carrier, a package housing, at least one LED unit, a light-permeable component, and a barrier component. The conductive carrier includes a functional region and a non-functional region that surrounds the functional region and has at least one metal sectional surface. The package housing encapsulates the conductive carrier and has an accommodating cavity, and the at least one metal sectional surface is exposed through the package housing. The at least one LED unit is disposed in the accommodating cavity and electrically connected to the functional region. The light-permeable component is disposed in the accommodating cavity and encapsulates the at least one LED unit. The barrier component is connected to the non-functional region, so as to isolate the at least one metal sectional surface exposed through the package housing from the external environment.

In one of the possible or preferred embodiments, a material of the package housing is different from a material of the barrier component.

In one of the possible or preferred embodiments, a difference in the coefficient of thermal expansion between the material of the package housing and the material of the barrier component is less than 200 ppm/°C.

In one of the possible or preferred embodiments, a compactness of the barrier component is greater than a compactness of the package housing.

In one of the possible or preferred embodiments, the package housing includes an outer wall surrounding and defining the accommodating cavity and a support layer integrally formed with the outer wall. The support layer covers the non-functional region and is interlocked therewith, and the at least one metal sectional surface is exposed between the outer wall and the support layer.

In one of the possible or preferred embodiments, an outer surface of the outer wall is coplanar with an outer surface of the barrier component.

In one of the possible or preferred embodiments, a thickness of the functional region is greater than a thickness of the non-functional region.

In one of the possible or preferred embodiments, the functional region is provided with a lead portion, and the non-functional region is provided with at least two extension portions that have the at least one metal sectional surface and are located on two opposite sides of the lead portion.

In one of the possible or preferred embodiments, the at least two extension portions are interfitted between the outer wall and the support layer.

In one of the possible or preferred embodiments, the package housing has a notch that penetrates through the support layer and corresponds in position to the at least two extension portions, and the barrier component is disposed in the notch.

In one of the possible or preferred embodiments, the notch has a first inner surface corresponding in position to the outer wall and a second inner surface corresponding in position to the at least two extension portions, and a rounded corner is formed at a junction between the first inner surface and the second inner surface.

In one of the possible or preferred embodiments, the maximum width of the notch is from 10% to 80% of the maximum width of the outer wall.

In one of the possible or preferred embodiments, the barrier component has a clearance recess spaced apart from the outer wall.

In one of the possible or preferred embodiments, the notch penetrates to the bottom of the outer wall, such that the barrier component is integrated with the outer wall into a unitary structure.

In one of the possible or preferred embodiments, the lead portion includes two lead units spaced apart from each other, and a portion of the support layer is filled into a gap between the two lead units. Furthermore, one of the at least two extension portions extends from one of the lead units, and another one of the at least two extension portions extends from the other of the lead units.

In one of the possible or preferred embodiments, the at least one LED unit is disposed on one of the lead units and electrically connected to the other of the lead units via at least one wire.

In order to solve the above-mentioned problems, another one of the technical aspects adopted by the present disclosure is to provide a method for manufacturing the LED package structure, which includes: providing a carrier frame that includes a plurality of conductive carriers and a plurality of connecting regions between the conductive carriers; forming a housing layer to encapsulate the carrier frame; forming a groove in each of the connecting regions and forming a barrier in each of the grooves; and performing a separation operation along the connecting regions. The separation operation includes separating the conductive carriers from each other, separating a plurality of package housings respectively corresponding to the conductive carriers from the housing layer, and separating each of the barrier materials into two barrier components respectively corresponding to adjacent two conductive carriers.

In one of the possible or preferred embodiments, the process of forming the groove in each of the connecting regions includes using a first cutting tool to perform a cutting operation along the connecting regions. Furthermore, the process of performing the separation operation includes using a second cutting tool to perform another cutting operation along the connecting regions, and a width of the second cutting tool is less than a width of the first cutting tool.

In one of the possible or preferred embodiments, in the cutting operation, the first cutting tool is used to form a fillet structure at the bottom of each of the grooves.

In one of the possible or preferred embodiments, the process of forming the barrier in each of the grooves includes filling liquid silicone into each of the grooves and curing the liquid silicone by heating.

In one of the possible or preferred embodiments, in the process of filling the liquid silicone into each of the grooves, the liquid silicone has a concave surface by controlling a filling amount of the liquid silicone.

In one of the possible or preferred embodiments, the process of forming the barrier in each of the grooves includes performing a vacuum degassing operation on the liquid silicone filled in each of the grooves.

In conclusion, in the LED package structure with high adhesion of the present disclosure, by virtue of the package housing encapsulating the conductive carrier, the at least one metal sectional surface exposed through the package housing, and the barrier component connected to the non-functional region to isolate the at least one metal sectional surface from the external environment, the adhesion between heterogeneous structures and the air-tightness at the packaging interface can be effectively increased, thereby improving the reliability and environmental resistance of the packaging structure.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of an LED package structure with high adhesion according to a first embodiment of the present disclosure;

FIG. 2 is a schematic top view of the LED package structure with high adhesion according to the first embodiment of the present disclosure;

FIG. 3 is a flowchart of a method for manufacturing the LED package structure with high adhesion according to a second embodiment of the present disclosure;

FIGS. 4 and 5 are schematic views of a process stage in step S100 and step S102 of the method for manufacturing the LED package structure with high adhesion according to the second embodiment of the present disclosure;

FIGS. 6-8 are schematic views showing a process stage in step S104 of the method for manufacturing the LED package structure with high adhesion according to the second embodiment of the present disclosure;

FIGS. 9 and 10 are schematic views of a process stage in step S106 of the method for manufacturing the LED package structure with high adhesion according to the second embodiment of the present disclosure; and

FIGS. 11-13 are schematic views of another process stage in step S104 of the method for manufacturing the LED package structure with high adhesion according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

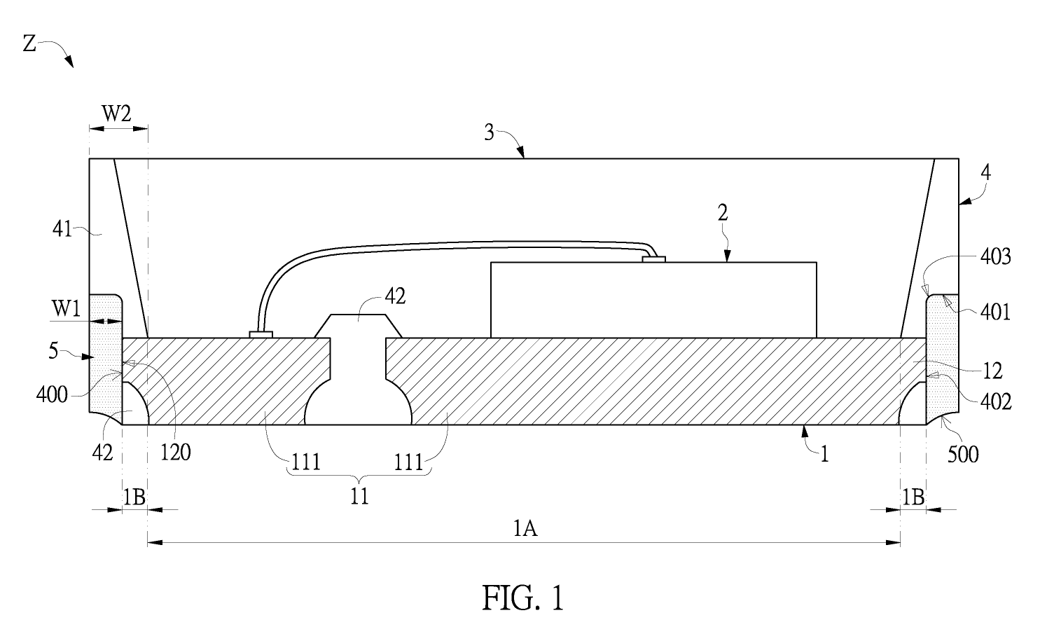

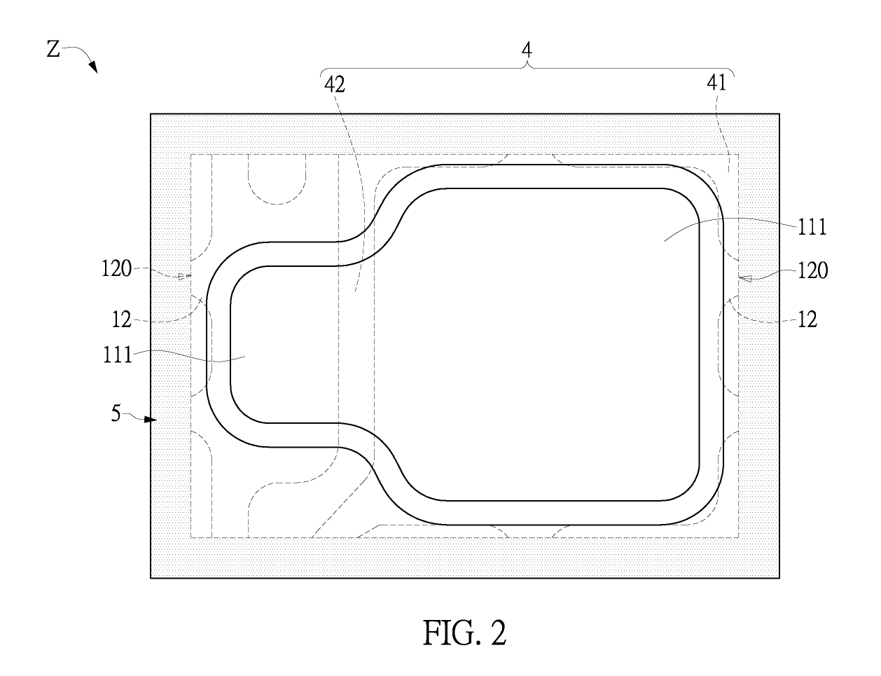

Referring to FIGS. 1 and 2, a first embodiment of the present disclosure provides an LED package structure Z with high adhesion, which includes a conductive carrier 1, at least one LED unit 2, a light-permeable component 3, a package housing 4, and a barrier component 5. In the present disclosure, the conductive carrier 1 is configured to provide mechanical support and conductive paths. The at least one LED unit 2 is bonded to the conductive carrier 1 so as to emit desired light. The light-permeable component 3 at least covers the at least one LED unit 2, and the package housing 4 at least surrounds the at least one LED unit 2 and the light-permeable component 3. The package housing 4 and the light-permeable component 3 can cooperatively provide the required protective functions, such as preventing external mechanical impacts and blocking the ingress of external substances (e.g., moisture or corrosive gases), thereby avoiding damage or performance degradation of the at least one LED unit 2. The barrier component 5 is disposed at the interface between the package housing 4 and the conductive carrier 1, effectively preventing external substances from infiltrating the interior along the packaging interface, thereby enhancing the overall airtightness and reliability of the package.

More specifically, the conductive carrier 1 includes a functional region 1A and a non-functional region 1B that surrounds the functional region 1A and has at least one metal sectional surface 120. The package housing 4 encapsulates the conductive carrier 1 and has an accommodating cavity, and the at least one metal sectional surface 120 is exposed through the package housing 4. The at least one LED unit 2 is disposed in the accommodating cavity and electrically connected to the functional region 1A of the conductive carrier 1. The light-permeable component 3 is disposed in the accommodating cavity and encapsulates the at least one LED unit 2. The barrier component 5 is connected to the non-functional region 1B of the conductive carrier 1, so as to isolate the at least one metal sectional surface 120 exposed through the package housing 4 from the external environment. The term “functional region” as used herein refers to a bonding area that provides conductive paths to achieve electrical connection between the at least one LED unit 2 and an external device.

The conductive carrier 1 can be a metal lead frame, in which a thickness of the functional region 1A is greater than a thickness of the non-functional region 1B. The at least one metal sectional surface 120 of the non-functional region 1B is a cut surface formed after the segmentation of the metal lead frame, and is unsuitable for use as an electrical contact. The at least one LED unit 2 can be a visible light LED and/or an invisible light LED. The light-permeable component 3 is configured to allow light emitted from the at least one LED unit 2 to pass through and provide mechanical protection for the at least one LED unit 2, and also helps to reduce negative effects caused by environmental factors such as moisture, dust, or chemicals. The light-permeable component 3 can be a transparent protective layer made of a transparent encapsulating material based on an epoxy resin system or a silicone resin system, but is not limited thereto.

The package housing 4 can be a resin housing made of any industrial resin material, such as an epoxy molding compound (EMC). The package housing 4 includes an outer wall 41 surrounding and defining the accommodating cavity and a support layer 42 integrally formed with the outer wall 41. The support layer 42 encapsulates the non-functional region 1B of the conductive carrier 1 and is interlocked therewith, forming a structural mechanical interlock through mutually complementary shapes. Furthermore, the non-functional region 1B of the conductive carrier 1 is interfitted between the outer wall 41 and the support layer 42, and the at least one metal sectional surface 120 is exposed between the outer wall 41 and the support layer 42. Therefore, the adhesion between the conductive carrier 1 and the package housing 4 can be improved.

More specifically, the functional region 1A of the conductive carrier 1 is provided with a lead portion 11, and the non-functional region 1B of the conductive carrier 1 is provided with at least two extension portions 12. The at least two extension portions 12 are located on two opposite sides of the lead portion 11 and interfitted between the outer wall 41 and the support layer 42. Only one of the at least two extension portions 12 may have the metal sectional surface 120, or alternatively, two or more of the at least two extension portions 12 each have the metal sectional surface 120. In practice, the lead portion 11 may include two lead units spaced apart from each other, and a gap between the two lead units 111 is filled with a portion of the support layer 42. The at least one LED unit 2 is disposed on one of the lead units 111 and electrically connected to the other of the lead units 111 via at least one wire. Furthermore, the at least two extension portions 12 may correspondingly extend from the two lead units 111. For example, a plurality of edges of each lead unit 111 may each have at least one extension portion 12 extending therefrom.

In certain embodiments, a functional coating is coated on outer surfaces (e.g., upper and lower surfaces) of the lead portion 11 and the extension portion 12 of the conductive carrier 1, so as to provide good anti-oxidation protection, increase conductivity, and improve bondability. The functional coating may be a silver plating layer, but is not limited thereto. The metal sectional surface 120 is formed by cutting with a tool, and at least a partial area of the metal sectional surface 120 is not covered with the functional plating layer.

The barrier component 5 may be disposed around the non-functional region 1B of the conductive carrier 1, for example, surrounding the non-functional region 1B of the conductive carrier 1, so as to completely cover at least one metal sectional surface 120. In practice, the barrier component 5 may be an annular structure, which is formed as a continuous or segmented structure extending along the boundary of the non-functional region 1B of the conductive carrier 1 below the outer wall 41, and is integrated with the outer wall 41 and the support layer 42. Preferably, an outer surface of the outer wall 41 is coplanar with an outer surface of the barrier component 5.

In the present disclosure, the package housing 4 has an annular notch 400 that extends toward the outer wall 41 and penetrates through the support layer 42 and the at least two extension portions 12. The annular notch 400 corresponds in position to the at least one metal sectional surface 120, and the barrier component 5 is disposed in the annular notch 400, so as to isolate the at least one metal sectional surface 120 exposed through the package housing 4 from the external environment. In practice, the annular notch 400 may be formed by cutting, and the maximum width W1 of the annular notch 400 is from 10% to 80% of the maximum width W2 of the outer wall 41. If necessary, the annular notch 400 may further penetrate to the bottom of the outer wall 41, such that the barrier component 5 in the annular notch 400 can be integrally formed with the outer wall 41. In addition, the barrier component 5 may be formed by filling the annular notch 400 with a sealing material.

More specifically, the annular notch 400 has a first inner surface 401 and a second inner surface 402. The first inner surface 401 corresponds in position to the outer wall 41, and the second inner surface 402 corresponds in position to the at least two extension portions 12. Furthermore, a rounded corner 403 is formed at a junction between the first inner surface 401 and the second inner surface 402 to improve filling property. In other words, the structure of the rounded corner 403 is beneficial for reducing the formation of voids during filling, thereby increasing the adhesion between the barrier component 5 and the conductive carrier 1 (or the package housing 4). In addition, by controlling material properties (e.g., flowability) or filling process parameters (e.g., a filling amount), the barrier component 5 may have a clearance recess 500 spaced apart from the outer wall 41, so as to reduce interference or obstruction during die bonding, thereby facilitating the precise positioning and attachment of the LED package structure Z. The clearance recess 500 may be a clearance notch, but is not limited thereto.

It is worth mentioning that a material of the barrier component 5 is different from a material of the package housing 4, such that the compactness of the barrier component 5 is greater than the compactness of the package housing 4. Therefore, the LED package structure Z of the present disclosure has a significant improvement in barrier capability against the ingress of external substances (e.g., moisture and corrosive gases) along the package interface. In order to reduce the risk of delamination caused by thermal stress, a difference in the coefficient of thermal expansion (CTE) between the material of the package housing 4 and the material of the barrier component is less than 200 ppm/°C. Therefore, stable adhesion between the package housing 4 and the barrier component 5 can be ensured. For example, when the material of the package housing 4 is EMC, the material of the barrier component 5 may be silicone.

### Second Embodiment

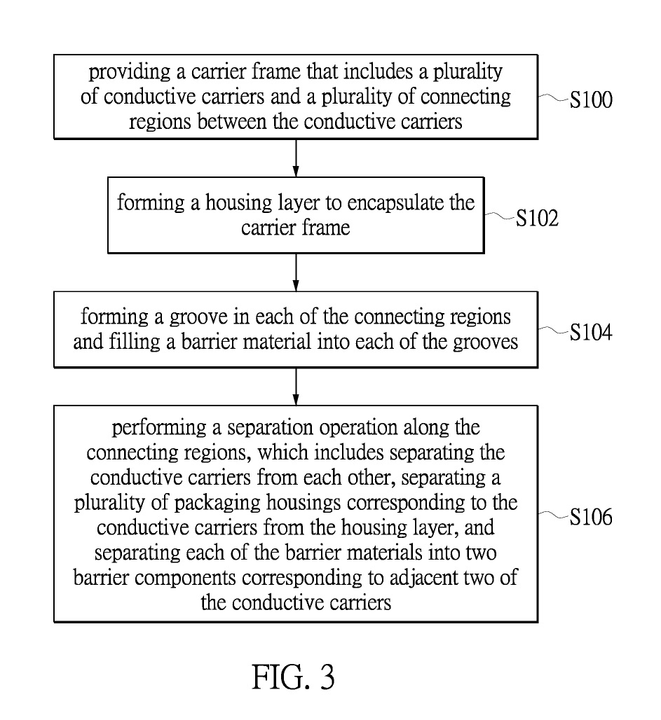

Referring to FIG. 3, a second embodiment of the present disclosure provides a method for manufacturing the LED package structure according to the first embodiment. The method includes: step S100, providing a carrier frame that includes a plurality of conductive carriers and a plurality of connecting regions between the conductive carriers; step S102, forming a housing layer to encapsulate the carrier frame; step S104, forming a groove in each of the connecting regions and forming a barrier in each of the grooves; and step S106, performing a separation operation along the connecting regions, which includes separating the conductive carriers from each other, separating a plurality of package housings corresponding to the conductive carriers from the housing layer, and separating each of the barrier materials into two barrier components corresponding to adjacent two of the conductive carriers.

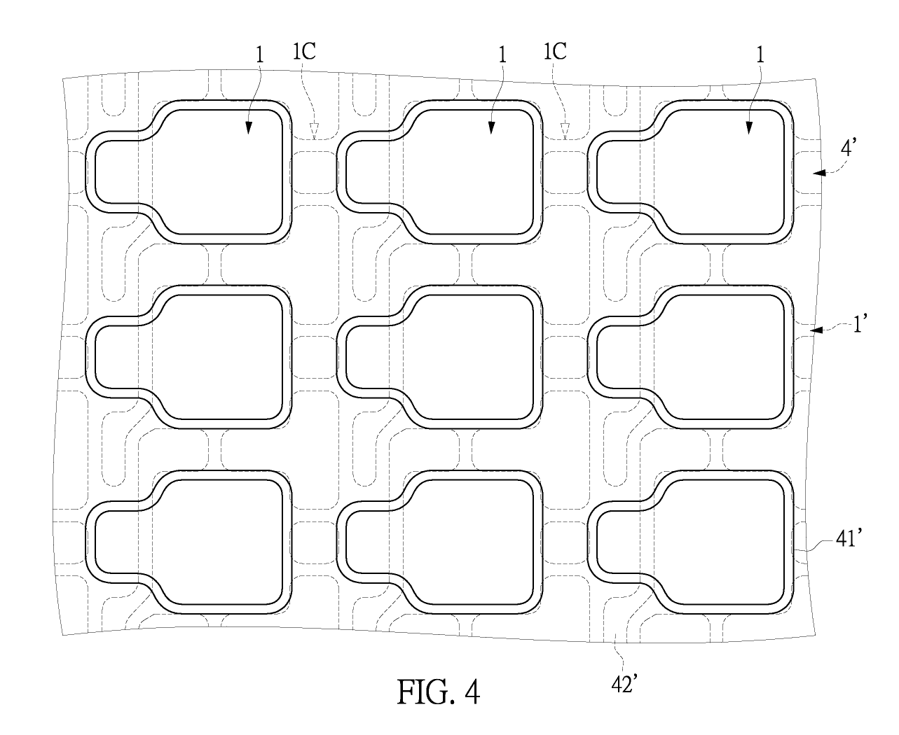

Reference is made to FIGS. 4 and 5, each of the connecting regions 1C of the carrier frame 1’ provided in step S100 is provided with one or more bridging structures (e.g., metal bars), so as to maintain the alignment and structural integrity among the conductive carriers 1. In step S102, the housing layer 4’ may be formed over the exterior of the carrier frame 1’ by molding, and is integrated with the carrier frame 1’ into a unitary structure, so as to provide mechanical protection and environmental isolation functions. The housing layer 4’ includes a wall layer 41’ and a base filler layer 42’. The wall layer 41’ is formed on the carrier frame 1’ and has a grid-like structure with a plurality of enclosing wall units (i.e., outer wall layers 41). The base filler layer 42’ is filled into the connecting regions 1C and frame gaps.

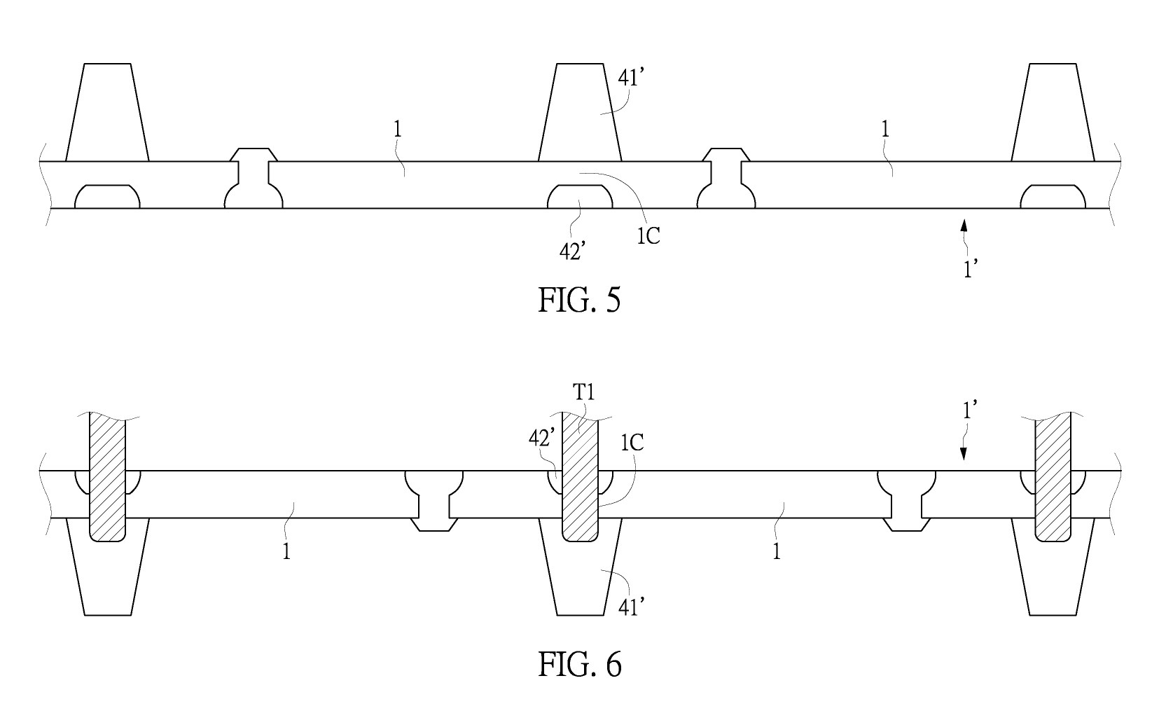

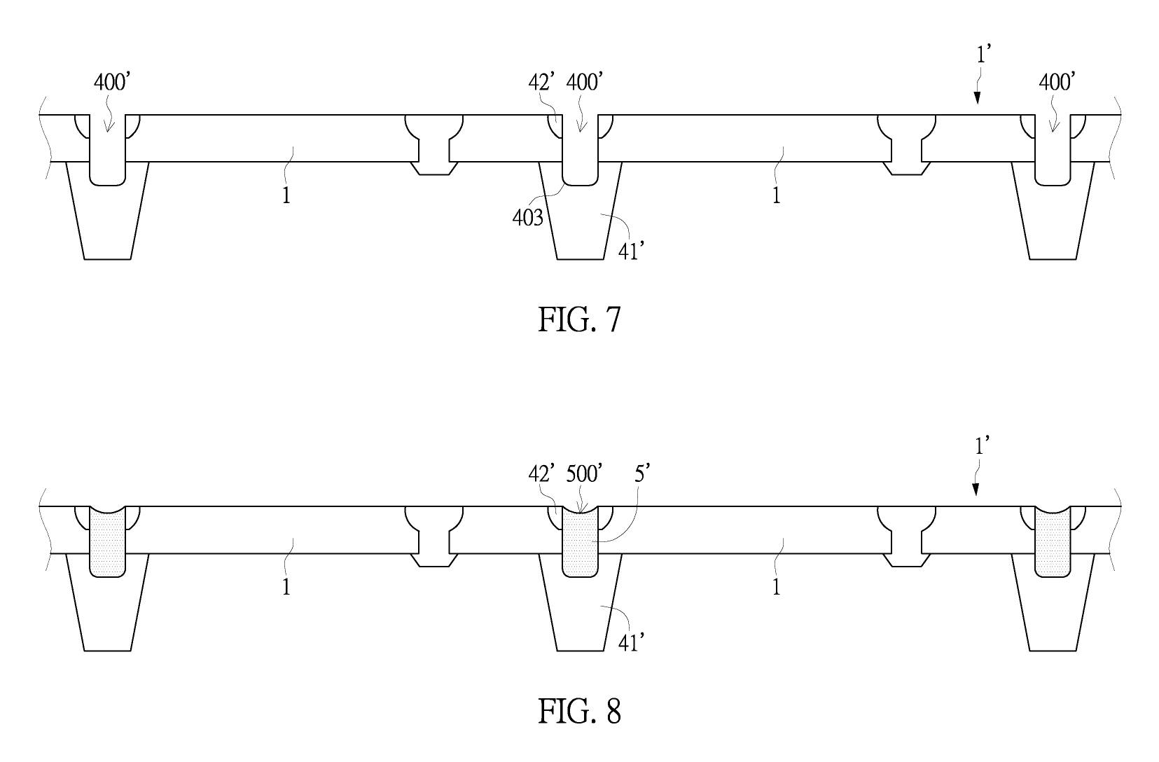

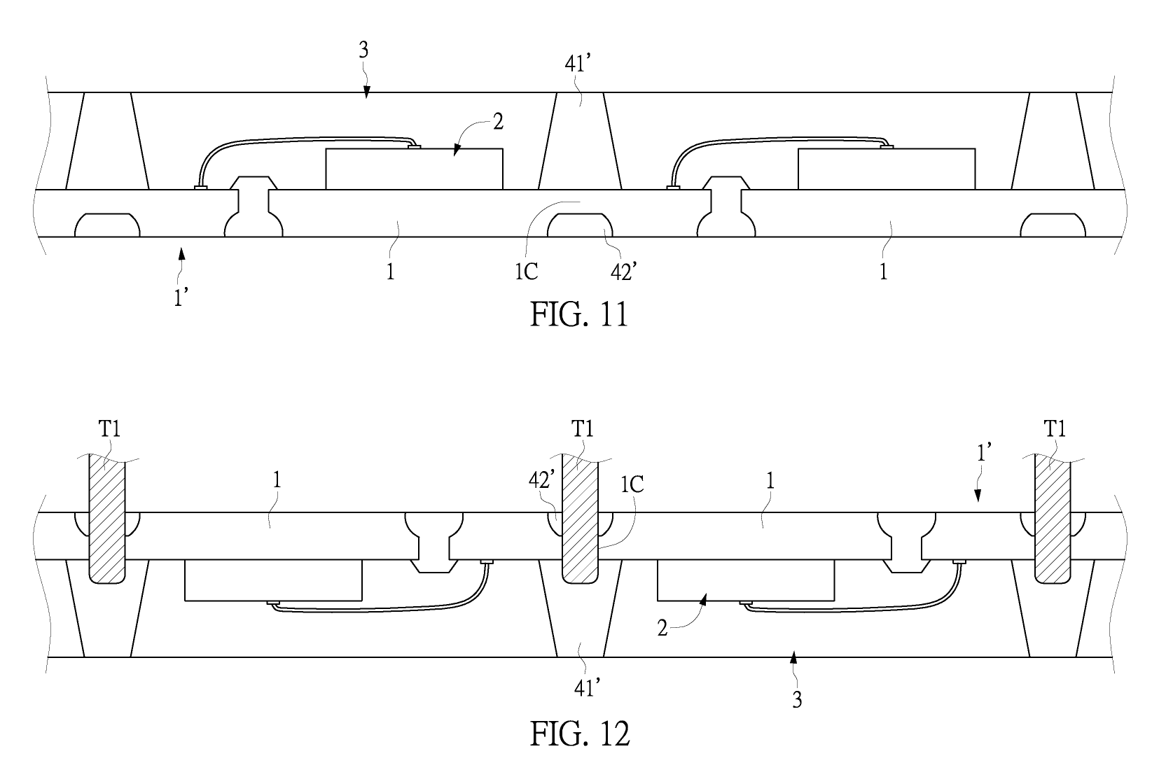

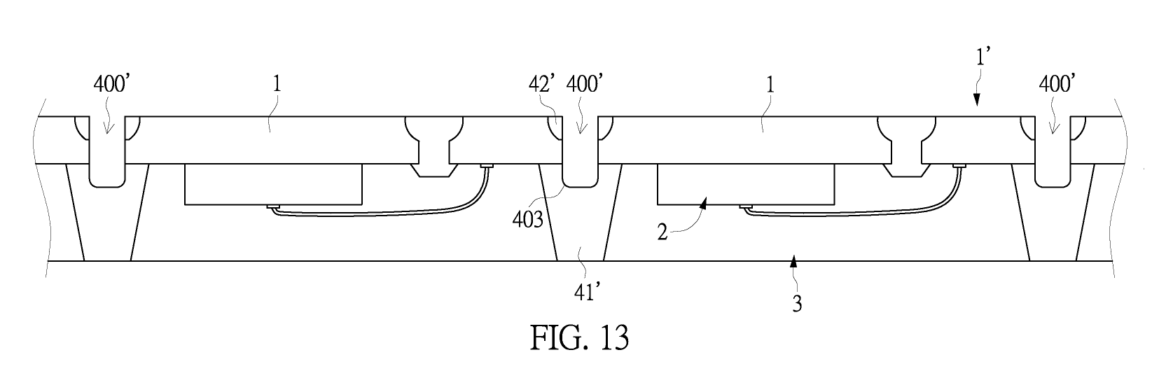

Reference is made to FIGS. 6-9 and 11-13. In step S104, a first cutting tool T1 is used to perform a cutting operation along the connecting regions 1C. The cutting operation is initiated from a side of the carrier frame 1’ opposite to the wall layer 41’, and has a cutting depth extending into the wall layer 41’. Specifically, the cutting depth at least reaches the entire thickness of the base filler layer 42’ and the connecting region 1C and a partial thickness of the wall layer 41’. Furthermore, in the cutting operation, the first cutting tool T1 can be used to form a fillet structure (i.e., rounded corner 403) at the bottom of the groove 400’, rather than a right-angle structure, so as to improve the filling property and avoid residual voids.

After the cutting operation is completed, liquid silicone may be filled into each of the grooves 400’ and then cured by heating. Furthermore, by controlling material properties (e.g., flowability) or filling process parameters (e.g., a filling amount), each of the grooves 400’ can be filled with a barrier 5’ formed from the cured liquid silicone and having a concave surface 500’. Accordingly, in a subsequent separation process, a barrier component 5 separated from the barrier 5’ may have a clearance recess 500, as shown in FIG. 1. Preferably, a vacuum degassing operation may be performed on the liquid silicone filled in each of the grooves 400’, so as to improve the compactness of the barrier component 5, thereby increasing the barrier performance of the overall package structure.

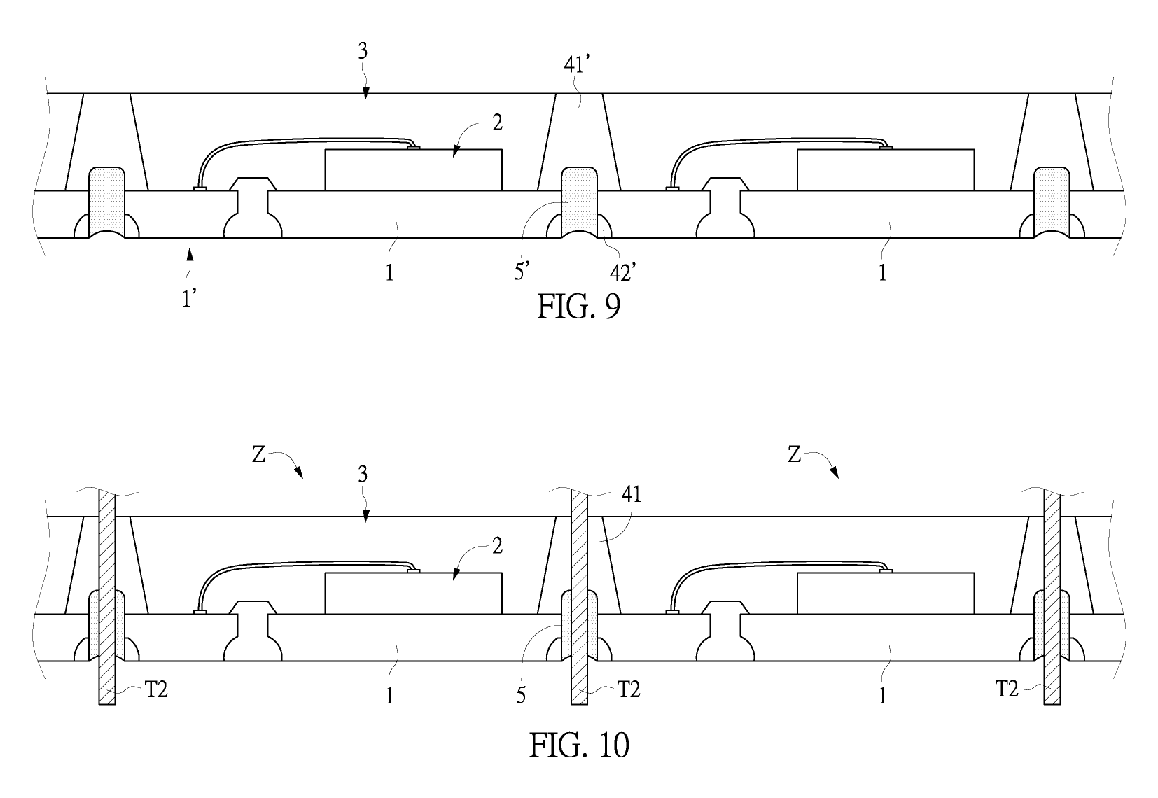

Reference is made to FIGS. 9 and 10. In step S106, a second cutting tool T2 is used to perform another cutting operation along the connecting regions 1C, in which the width of the second cutting tool T2 is smaller than that of the first cutting tool T1. The another cutting operation is initiated from the wall layer and aligned with the barriers 5’, and has a cutting depth at least reaching the entire thickness of the wall layer 41’ and the barriers 5’. That is, the cutting depth is sufficient to penetrate through the entire thickness of the wall layer 41’ and the barriers 5’ to sever the wall layer 41’ and the barriers 5’ into two parts at the middle, thereby singulating a plurality of mutually independent package structures.

In practice, the method of the present disclosure can perform a die and wire bonding process of a plurality of LED units 2 and a dispensing process of a plurality of light-permeable components 3 before step S102 is completed, and step S104 and step S106 are subsequently performed. Alternatively, the method of the present disclosure can perform the die and wire bonding process of the LED units 2 and the dispensing process of the light-permeable components 3 before step S104 is completed, and step S106 is subsequently performed. However, the above description is for exemplary purposes only, and is not meant to limit the scope of the present disclosure.

### Beneficial Effects of the Embodiments

In conclusion, in the LED package structure with high adhesion of the present disclosure, by virtue of the package housing encapsulating the conductive carrier, the at least one metal sectional surface exposed through the package housing, and the barrier component connected to the non-functional region to isolate the at least one metal sectional surface from the external environment, the adhesion between heterogeneous structures and the air-tightness at the packaging interface can be effectively increased, thereby improving the reliability and environmental resistance of the packaging structure.

More specifically, the non-functional region of the conductive carrier (the extension portions extending from the lead portion) is interfitted between the outer wall layer and the support layer of the package housing. Therefore, the adhesion between the conductive carrier and the package housing can be increased.

More specifically, a material of the barrier component is different from a material of the package housing, such that the compactness of the barrier component is greater than the compactness of the package housing. Furthermore, a difference in the coefficient of thermal expansion (CTE) between the material of the package housing and the material of the barrier component is less than 200 ppm/°C. Therefore, the risk of delamination caused by thermal stress can be reduced, and stable adhesion between the package housing and the barrier component can be ensured.

More specifically, the barrier component may be formed by filling the notch of the package housing with a sealing material, and the notch is formed with a rounded corner, so as to improve filling property and avoid residual voids. Furthermore, the barrier component may have a clearance recess formed at the bottom thereof, so as to reduce interference or obstruction during die bonding, thereby facilitating the precise positioning and attachment of the LED package structure Z.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An LED package structure with high adhesion, comprising:
a conductive carrier including a functional region and a non-functional region that surrounds the functional region and has at least one metal sectional surface;
a package housing encapsulating the conductive carrier and having an accommodating cavity, wherein the at least one metal sectional surface is exposed through the package housing;
at least one LED unit disposed in the accommodating cavity and electrically connected to the functional region;
a light-permeable component disposed in the accommodating cavity and encapsulating the at least one LED unit; and
a barrier component connected to the non-functional region, so as to isolate the at least one metal sectional surface exposed through the package housing from the external environment.

2. The LED package structure according to claim 1, wherein a material of the package housing is different from a material of the barrier component.

3. The LED package structure according to claim 2, wherein a difference in the coefficient of thermal expansion between the material of the package housing and the material of the barrier component is less than 200 ppm/°C.

4. The LED package structure according to claim 2, wherein a compactness of the barrier component is greater than a compactness of the package housing.

5. The LED package structure according to claim 1, wherein the package housing includes an outer wall surrounding and defining the accommodating cavity and a support layer integrally formed with the outer wall, the support layer covers the non-functional region and is interlocked therewith, and the at least one metal sectional surface is exposed between the outer wall and the support layer.

6. The LED package structure according to claim 5, wherein an outer surface of the outer wall is coplanar with an outer surface of the barrier component.

7. The LED package structure according to claim 5, wherein a thickness of the functional region is greater than a thickness of the non-functional region.

8. The LED package structure according to claim 5, wherein the functional region is provided with a lead portion, and the non-functional region is provided with at least two extension portions that have the at least one metal sectional surface and are located on two opposite sides of the lead portion.

9. The LED package structure according to claim 8, wherein the at least two extension portions are interfitted between the outer wall and the support layer.

10. The LED package structure according to claim 8, wherein the package housing has a notch that penetrates through the support layer and corresponds in position to the at least two extension portions, and the barrier component is disposed in the notch.

11. The LED package structure according to claim 10, wherein the notch has a first inner surface corresponding in position to the outer wall and a second inner surface corresponding in position to the at least two extension portions, and a rounded corner is formed at a junction between the first inner surface and the second inner surface.

12. The LED package structure according to claim 10, wherein a maximum width of the notch is from 10% to 80% of a maximum width of the outer wall.

13. The LED package structure according to claim 10, wherein the barrier component has a clearance recess spaced apart from the outer wall.

14. The LED package structure according to claim 10, wherein the notch penetrates to the bottom of the outer wall, such that the barrier component is integrated with the outer wall into a unitary structure.

15. The LED package structure according to claim 8, wherein the lead portion includes two lead units spaced apart from each other, and a portion of the support layer is filled into a gap between the two lead units, and wherein one of the at least two extension portions extends from one of the lead units, and another one of the at least two extension portions extends from the other of the lead units.

16. The LED package structure according to claim 15, wherein the at least one LED unit is disposed on one of the lead units and electrically connected to the other of the lead units via at least one wire.

17. A method for manufacturing the LED package structure as claimed in claim 1, comprising:
providing a carrier frame that includes a plurality of conductive carriers and a plurality of connecting regions between the conductive carriers;
forming a housing layer to encapsulate the carrier frame;
forming a groove in each of the connecting regions and forming a barrier in each of the grooves; and
performing a separation operation along the connecting regions, wherein the separation operation includes separating the conductive carriers from each other, separating a plurality of package housings respectively corresponding to the conductive carriers from the housing layer, and separating each of the barrier materials into two barrier components respectively corresponding to two adjacent ones of the conductive carriers.

18. The method according to claim 17, wherein the process of forming the groove in each of the connecting regions includes using a first cutting tool to perform a cutting operation along the connecting regions; and wherein the process of performing the separation operation includes using a second cutting tool to perform another cutting operation along the connecting regions, and a width of the second cutting tool is less than a width of the first cutting tool.

19. The method according to claim 18, wherein, in the cutting operation, the first cutting tool is used to form a fillet structure at the bottom of each of the grooves.

20. The method according to claim 17, wherein the process of forming the barrier in each of the grooves includes filling liquid silicone into each of the grooves and curing the liquid silicone by heating.

21. The method according to claim 20, wherein, in the process of filling the liquid silicone into each of the grooves, the liquid silicone has a concave surface by controlling a filling amount of the liquid silicone.

22. The method according to claim 21, wherein the process of forming the barrier in each of the grooves includes performing a vacuum degassing operation on the liquid silicone filled in each of the grooves.
